(19) United States
(12) Patent Application Publication
(10) Pub. No.: US 2019/0376184 A1
(43) Pub. Date: Dec. 12, 2019

(54) CHEMICAL VAPOR DEPOSITION SHOWER HEAD FOR UNIFORM GAS DISTRIBUTION

(71) Applicant: Lam Research Corporation, Fremont, CA (US)

(72) Inventors: Michael John SELEP, Portland, OR (US); Andrew James BORTH, Newberg, OR (US); John Michael WILTSE, Lake Oswego, OR (US); Damien Martin SLEVIN, Salem, OR (US); Eric MADSEN, Sherwood, OR (US)

(21) Appl. No.: 16/006,591

(22) Filed: Jun. 12, 2018

(51) Int. Cl. C23C 16/455; C23C 16/52

(52) U.S. Cl. CPC C23C 16/45565; C23C 16/52

(57) ABSTRACT

A Chemical Vapor Deposition (CVD) tool providing more even flow and distribution of reagent gasses over a substrate. The CVD tool includes a processing chamber and a shower head. The shower head includes a gas dispensing surface having multiple hole patterns that are preferably, but not exclusively, non-symmetrical patterns that mitigate or eliminate lines or symmetry. Such hole patterns include are a variety of different types of spirals or close approximations thereof, include, but are not limited to, Archimedean, Vogel or Fermat spirals.

### BACKGROUND

Chemical Vapor Deposition (CVD) tools are used for depositing thin films on substrates. One type of CVD tool, called a Plasma Enhanced CVD or “PECVD” tool, includes a process chamber, a substrate holder for positioning a substrate in the process chamber, and a shower head. During operation, the shower head distributes a reactant gas above the surface of the substrate to be processed. A Radio Frequency (RF) potential is applied to the shower head, and possibly the substrate holder as well, to generate a plasma. Energized electrons ionize or dissociate (e.g., “crack”) reactant gasses from the plasma, creating chemically reactive radicals. As these radicals react, they deposit and form a thin film on the substrate.

One issue with current shower heads used for PECVD is that the holes provided on the shower head for gas distribution are typically arranged in symmetrical patterns. With symmetrical patterns, macroscopic areas, along the lines of symmetry, tend to form where the velocity vector of the reactant gas exiting the shower head has zero azimuthal velocity and/or stagnate completely. As a result, certain properties of the thin film deposited on the substrate can be non-uniform. In addition, in the locations of stagnant gas flow, the deposited film is susceptible to defects. With certain types of substrates, such as semiconductor wafers, defects are a problem because they may result in non-functioning die, reducing fabrication yields.

An improved shower head design for deposition tools is therefore needed.

### SUMMARY

A shower head for a Chemical Vapor Deposition (CVD) tool that provides more even gas distribution, resulting in improved uniformity of deposited layers and fewer defects on substrates, is disclosed. The shower head includes a gas dispensing surface having a first set of holes arranged in a first spiral pattern, the first set of holes in fluid communication with a first supply of a first gas and a second set of holes arranged in a second pattern, the second set of holes in fluid communication with a second supply of a second gas, and possibly additional sets of holes in fluid communication with additional supplies of additional gasses. The various patterns reduce or altogether eliminate stagnant or uneven gas flow at the gas dispensing surface of the shower head. Such patterns are preferably, but not exclusively, non-symmetrical patterns that mitigate or eliminate lines or symmetry, allowing for a highly uniform gas flow in the vicinity of the gas dispensing surface of the shower head and above the substrate to be processed. By using non-symmetrical patterns, such as various types of spirals, deposition layers are significantly more uniform, resulting in fewer defects and higher yields.

In non-exclusive embodiments, the patterns of one or more sets of holes are a variety of different types of spirals or close approximations thereof. Examples of such spirals may include, but are not limited to, Archimedean, Vogel, or Fermat spirals.

In yet other embodiments, the various types of spirals may be arranged in a number of different ways on the gas distribution surface of the shower head. Such arrangements may include, but are not limited to, concentric, non-concentric, clock-wise and counter-clockwise spirals, spirals with holes of different sizes, spirals with holes of different densities, three or more spiral patterns, etc.

In yet other embodiments, one or more of the patterns may be spirals, but the remainder of the patterns may be symmetrical. The various patterns may each be supplied by separate plenums.

### BRIEF DESCRIPTION OF THE DRAWINGS

The present application, and the advantages thereof, may best be understood by reference to the following description taken in conjunction with the accompanying drawings in which:

FIG. 1 is a block diagram of a Chemical Vapor Deposition (CVD) chamber in accordance with a non-exclusive embodiment of the invention.

FIG. 2 is a cross-sectional view of a shower head in accordance with a non-exclusive embodiment of the invention.

FIG. 3 is a block diagram illustrating a controller for controlling flow rate and pressure of gasses into the shower head in accordance with a non-exclusive embodiment of the invention.

FIGS. 4A through 4I are various exemplary shower heads having multiple hole patterns and at least two gas plenums in accordance with various embodiments of the invention.

FIG. 5 is a diagram of a plenum in accordance with a non-exclusive embodiment of the invention.

In the drawings, like reference numerals are sometimes used to designate like structural elements. It should also be appreciated that the depictions in the figures are diagrammatic and not necessarily to scale.

### DETAILED DESCRIPTION

The present application will now be described in detail with reference to a few non-exclusive embodiments thereof as illustrated in the accompanying drawings. In the following description, numerous specific details are set forth in order to provide a thorough understanding of the present disclosure. It will be apparent, however, to one skilled in the art, that the present discloser may be practiced without some or all of these specific details. In other instances, well known process steps and/or structures have not been described in detail in order to not unnecessarily obscure the present disclosure.

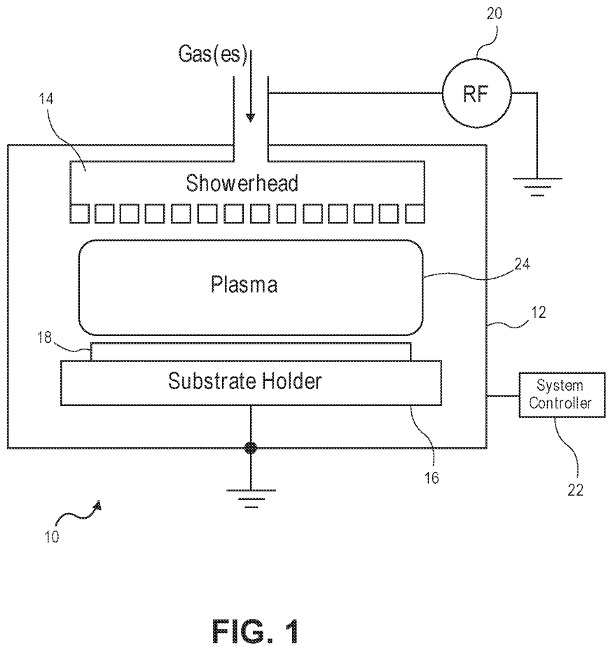

Referring to FIG. 1, a block diagram of a Chemical Vapor Deposition (CVD) tool 10 is illustrated The CVD tool 10 includes a processing chamber 12, a shower head 14, a substrate holder 16 for holding and positioning a substrate 18 to be processed, a Radio Frequency (RF) generator 20, and a system controller 22. In various embodiments, the CVD tool may be Plasma Enhanced (PECVD), a Low Pressure (LPCVD), Ultra High Vacuum (UHVCVD), Atomic Layer Deposition (ALD), Plasma-Enhanced Atomic Layer Deposition (PEALD) or any other type of CVD tool.

During operation, reactant gas(es) are supplied into the process chamber 12 through the shower head 14. Within the shower head 14, the gas(es) is/are distributed via one or more plenums (not illustrated) into the chamber 12, in the general area above the surface of the substrate 18 to be processed. An RF potential, generated by the RF generator 20, is applied to an electrode (not illustrated) on the shower head 14. An RF potential may also possibly be applied to the substrate holder 18 (also not shown) as well. The RF potential generates a plasma 24 within the processing chamber 12. Within the plasma 24, energized electrons ionize or dissociate (i.e., “crack”) from the reactant gas(es), creating chemically reactive radicals. As these radicals react, they deposit and form a thin film on the substrate 18.

In various embodiments, the RF generator 20 may be a single RF generator or multiple RF generators capable of generating high, medium and/or low RF frequencies. For example, in the case of high frequencies, the RF generator 20 may generate frequencies ranging from 2-100 MHz and preferably 13.56 MHz or 27 MHz. When low frequencies are generated, the range is 50 KHz to 2 MHz, and preferably 350 to 600 KHz

The system controller 22 is employed to control operation of the CVD tool 10 in general and process conditions during deposition, post deposition, and/or other process operations. The controller 22 typically includes one or non-transient computer readable medium devices for storing system control software or code computer and one or more processors for executing the code. The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. The processor may include a CPU or computer, multiple CPUs or computers, analog and/or digital input/output connections, motor controller boards, etc.

In certain embodiments, the controller 22, running or executing the system software or code, controls all or at least most of the activities of the tool 10, including such activities as controlling the timing of the processing operations, frequency and power of operations of the RF generator 20, pressure within the processing chamber 12, flow rates, concentrations and temperatures of gas(es) into the process chamber 12 and their relative mixing, temperature of a substrate 18 supported by the substrate holder 16, etc.

The controller 22 may also include a user interface (not shown). The user interface may include a display screen, graphical software displays of indicative of operating parameters and/or process conditions of the tool 10, and user input devices such as pointing devices, keyboards, touch screens, microphones, etc., that allow a human operator to interface with the tool 10.

Information transferred between the system controller 22 and the various components of the tool 10 may be in the form of signals such as electronic, electromagnetic, optical, or other signals capable of being transmitted and/or received via any communication link that carries signals and may be implemented using wire or cable, fiber optics, a phone line, a cellular phone link, a radio frequency link, and/or other communication channels.

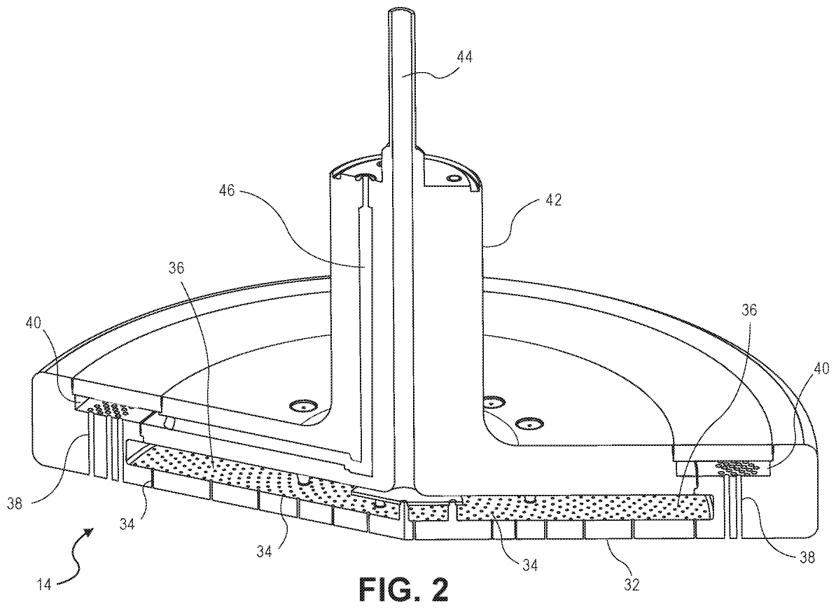

Referring to FIG. 2, a cross-sectional view of a shower head 14 is shown. The shower head 14 includes a gas dispensing surface 32, a first set of holes 34, a first plenum 36, a second set of holes 38, a second plenum 40, a stem 42, first gas conduit 44 and a second gas conduit 46 provided within the stem 42. In accordance with various embodiments, the first set of holes 34 and the second set of holes 38 are each arranged in various patterns on the gas dispensing surface 32 of the shower head 14 as described in more detail below. The holes 34, 38, regardless of embodiment, are opposed to the substrate 18 along the gas dispensing surface 32. With this arrangement, gas(es) are distributed immediately above the surface of the substrate 18 to be processed during operation.

The first gas conduit 44 is in fluid communication with the first plenum 36. In turn, the first plenum 36 is in fluid communication with each of the first set of holes 34. With this arrangement, gas supplied into the first gas conduit 44 flows into the first plenum 36 and then through the first set of holes 34 and through the gas dispensing surface 32 of the shower head 14.

The second gas conduit 46 is in fluid communication with the second plenum 40. In turn, the second plenum 40 is in fluid communication with each of the second set of holes 38. With this arrangement, gas supplied into the second gas conduit 46 flows into the second plenum 40 and then through the second set of holes 38 and through the gas dispensing surface 32 of the shower head.

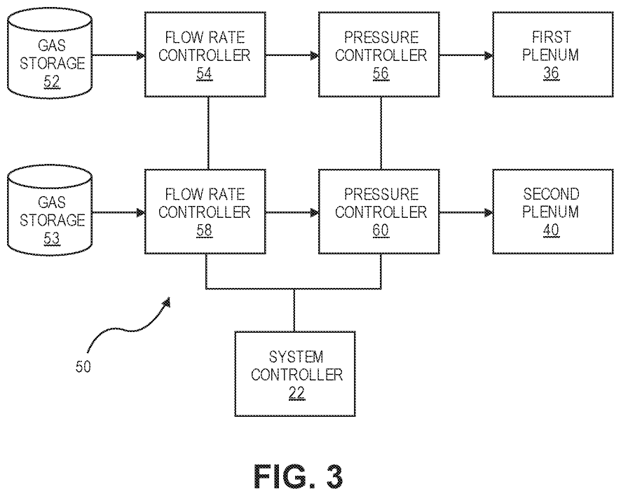

Referring to FIG. 3, a block diagram 50 illustrating control of flow rate and pressure of gas(es) into the shower head 14 is shown. In this embodiment, it is assumed that the gas supplied to the first plenum 36 and the second plenum 40 are different. As such, first and second gas storage devices 52 and 53 are provided to supply a first gas to the first plenum 36 and a second gas to the second plenum 40. If the gas supplied to the two plenums 36, 40 is the same, then only one gas storage device may be needed.

The first gas and the second gas may be different in a number of ways. For instance, the two gases may be entirely different (e.g. one oxygen, the other hydrogen). Alternatively, the two gases may be in fact the same gas, but supplied to the shower head 14 at either (a) different flow rates, (b) different pressures and/or (c) both different pressures and flows rates. The two gases may include the same mixture of two or more gases, but differ in the ratio of the two gases. In various embodiments, the gases may include any gas, including but not limited to reagant gasses, such as silane, dichlorosilane, oxygen, nitrous oxide, hydrogen, tetraethoxysilane, helium, fluorine, nitrogen, argon, acetylene, atomic oxygen, atomic fluorine, and mixtures thereof.

For the first gas, a flow rate controller 54 and a pressure controller 56 are provided between the gas storage device 52 and the first plenum 38. Under the direction of the system controller 22, the flow rate controller 54 controls the flow rate of gas from the storage device 52 via conduit 44 into the plenum 38 and the pressure controller 56 controls the pressure in the plenum 38. For the second gas, flow rate controller 58 and pressure controller 60, also under the direction of the system controller 22, control the flow rate of pressure of the second gas from gas storage device 53 via conduit 46 into the second plenum 40.

The first and second sets of holes 34, 38 may be arranged in various patterns that reduce or altogether eliminate stagnant or uneven gas flow at the gas dispensing surface 32 of the shower head 14. Such patterns are preferably, but not exclusively, non-symmetrical patterns that mitigate or eliminate lines or symmetry, allowing for a highly uniform gas flow in the vicinity of the gas dispensing surface 32 of the shower head 14 and above the substrate 18. By using these non-symmetrical patterns, such as various types of spirals, deposition layers are significantly more uniform, resulting in fewer defects and higher yields.

### Spirals

Archimedean Spirals:

Hole patterns used on the gas distributing surface 32 of showerhead 14 can be described as points located along a generalized Archimedean spiral described by r=c(θ/a)^{d}. The points are chosen such that the azimuthal coordinate θ of each point in this pattern is incremented from the θ coordinate of the preceding point by a certain constant angle a.

The Cartesian coordinates (x, y) for the n^{th} element in the pattern can be described by:

x=xₒ+sₓr cos θ

y=yₒ+s_{y}r sin θ

where:

rₙ=cn^{d}

θₙ=θₒ+na

d∈[0.05, 2.00]. d=½ for a Fermat spiral.

$$ϕ = \frac{1 + \sqrt{5}}{2} .$$

is the θ coordinate increment between successive elements.

The parameter b is an element of the set of all numbers which have a continued fraction representation requiring ≥4 terms. This definition includes irrational numbers. To yield a uniform pattern that maintains uniform element packing and does not develop local structure (such as “spoke” features) over an arbitrarily large number of points, the parameter b is preferred to be the golden ratio

$$a = 2 π ( 1 - \frac{1}{b} )$$

θₒ∈ [symbol] is the pattern rotation in radians (nominally 0).

xₒ ∈ [symbol] is the x coordinate offset (nominally 0).

yₒ ∈ [symbol] is the y coordinate offset (nominally 0).

sₓ∈ [symbol] is the x coordinate scale factor (nominally 1).

s_{y}∈ [symbol] is the y coordinate scale factor (nominally 1).

c∈ [symbol] is the pattern scale factor.

Varying d changes the radial density gradient of the pattern. The pattern is uniformly dense when d=½. For a continuous curve, the term c/(a^{d}) scales the spiral larger or smaller, and d changes how the spiral is “wrapped”.

It is not necessary for the parameter b to be an irrational number. When b=φ, the elements in the pattern show uniform packing and appear not to exhibit local structures such as spokes. However, patterns may be generated using other values of b in which a ring-shaped subset of the pattern appears uniform and non-structured similar to a pattern generated by b=φ. For example, a pattern with such regions can be generated where b is a rational number such as:

$$b = 6 + \frac{1}{5 + \frac{1}{4 + \frac{1}{2 + 0}}}$$

In general, it may be difficult to yield a pattern that is uniform and non-structured when b is a continued fraction representable by less than three terms.

Fermat's Spiral:

A Fermat's spiral is an Archimedean spiral. In the case where d=0.5, the continuous spiral on which the points are located is called Fermat's spiral.

Vogel Spiral:

When d=½ and b=φ, the resulting pattern is known as a Vogel spiral. This pattern is characterized by uniform density, lack of local structure, and even packing of pattern points (where the distance from a given point to its nearest neighbor is very nearly equal to the distance to its fourth-nearest neighbor).

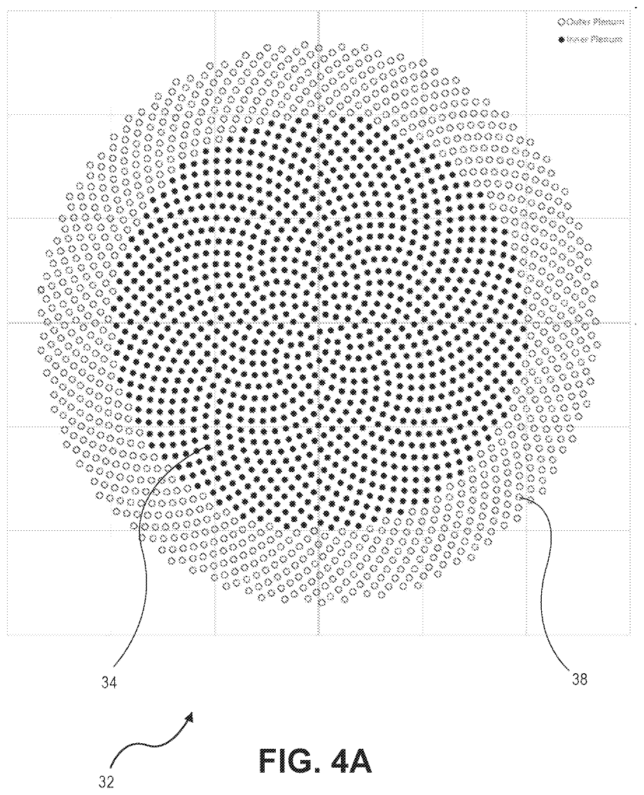

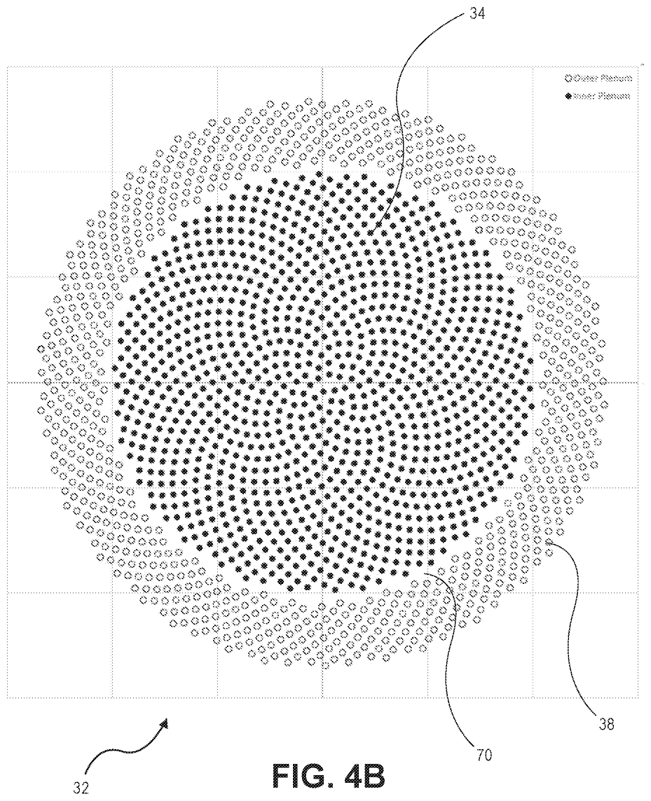

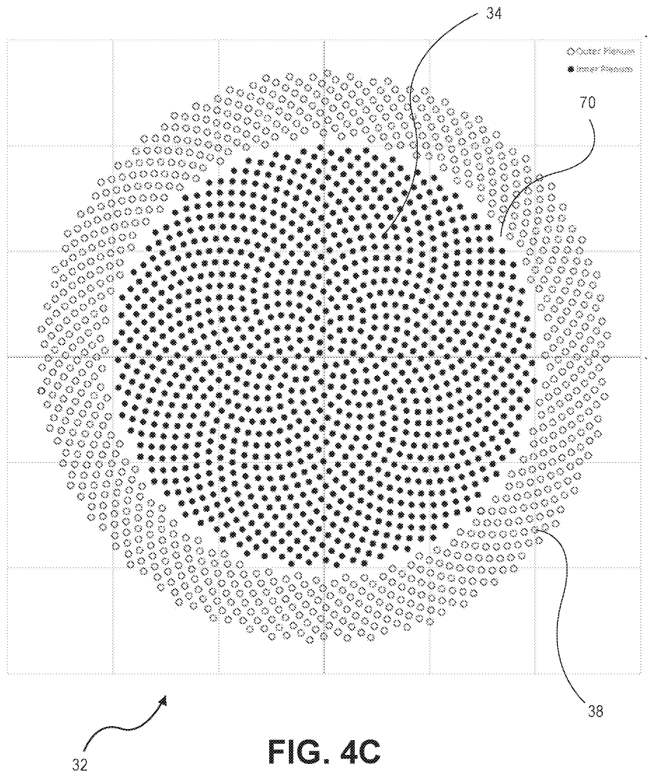

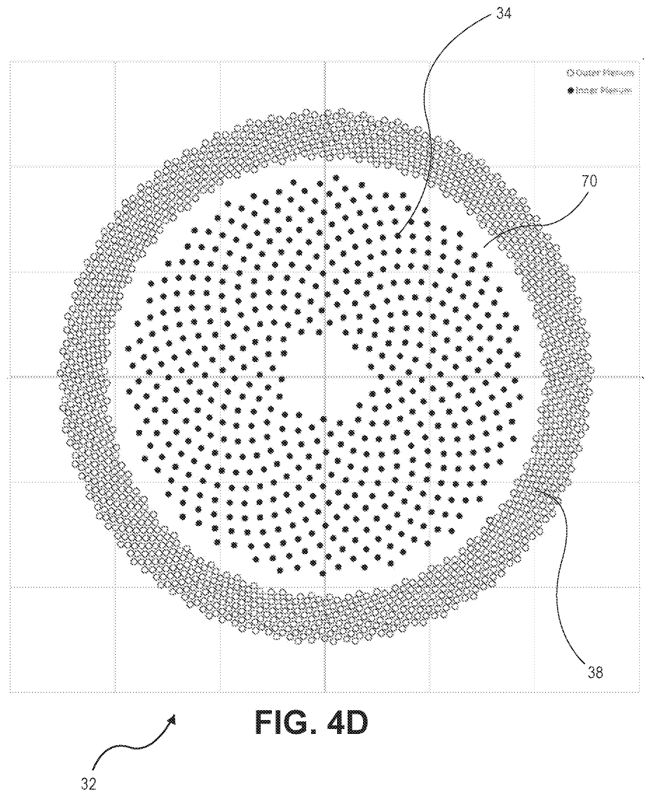

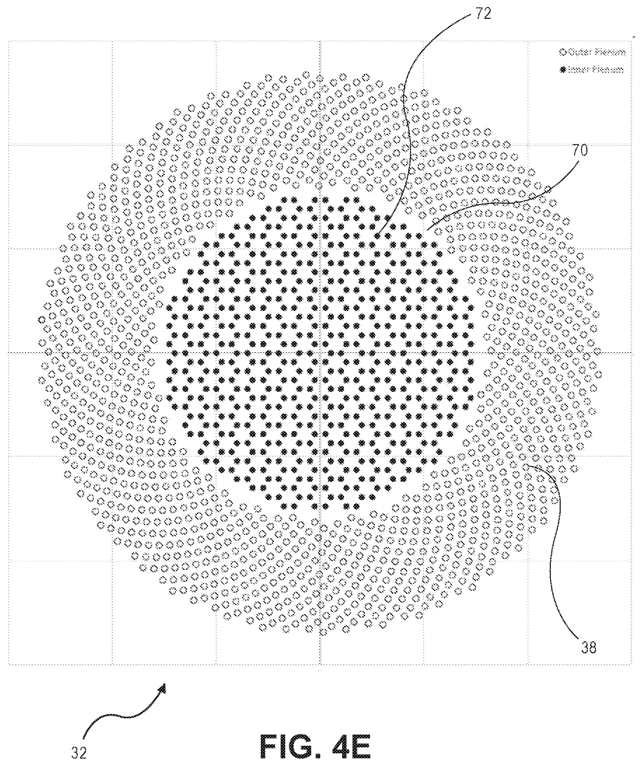

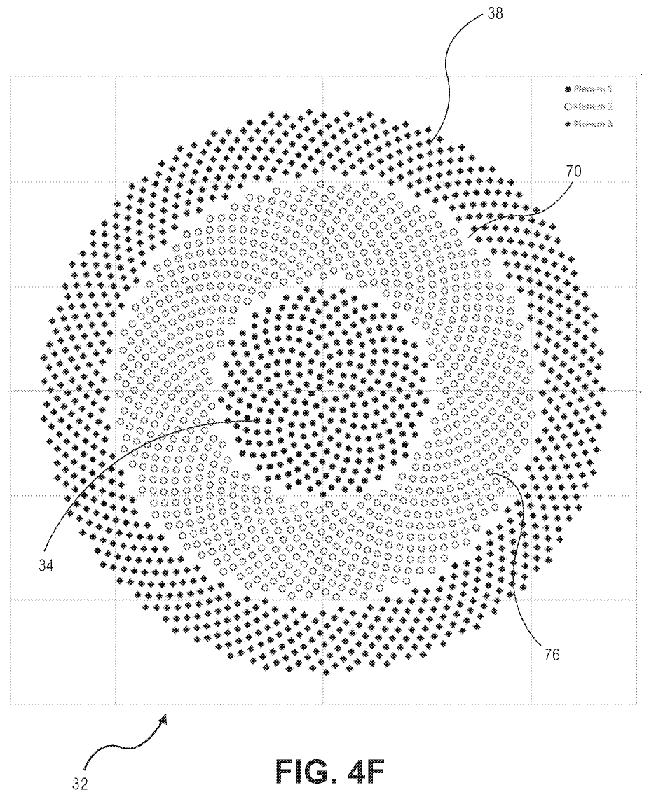

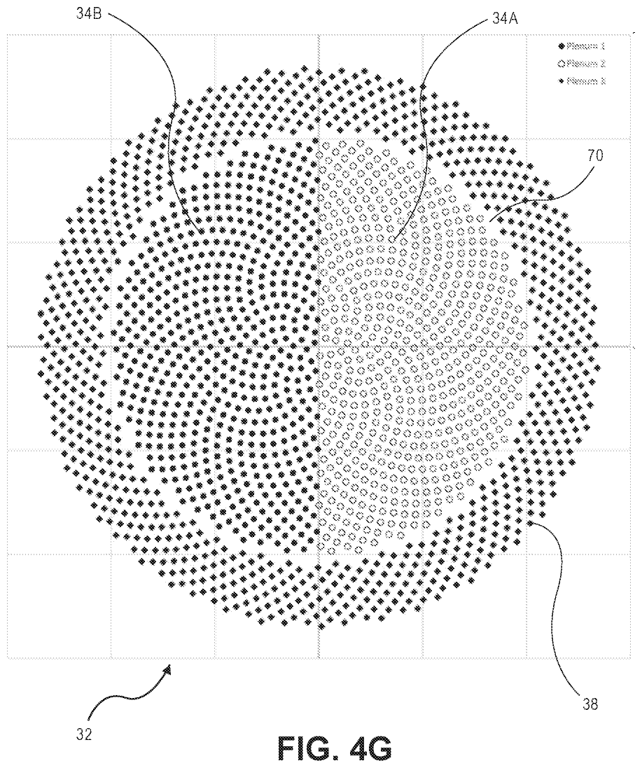

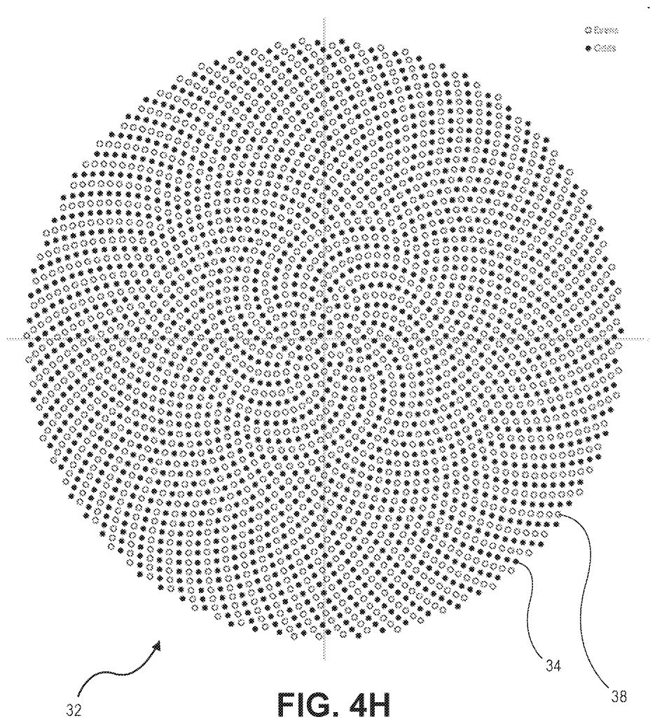

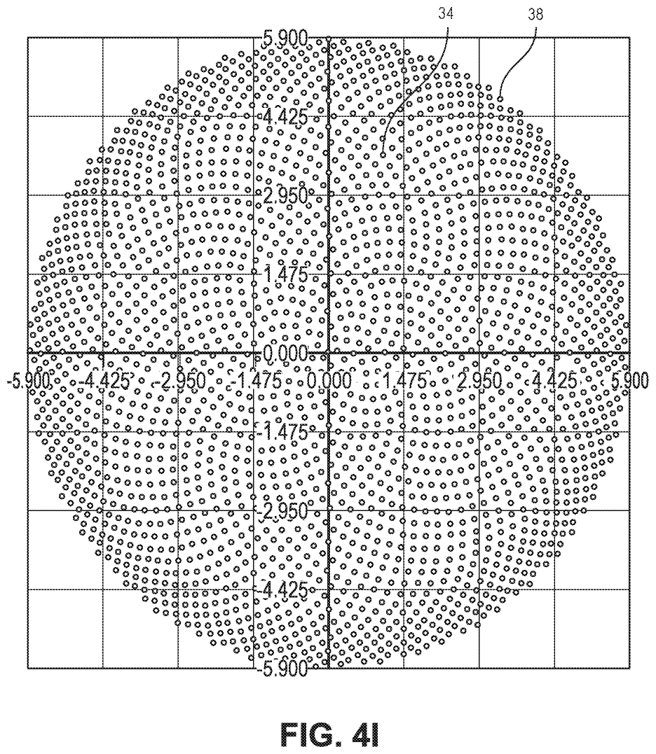

FIGS. 4A through 4I are various exemplary shower heads having either (a) two spiral hole patterns and two plenums or (b) one spiral pattern, one non-spiral pattern and two plenums in accordance with multiple embodiments of the invention. As used herein, the term “spiral” is intended to include, but is not limited to, any of the types of spirals as described herein. The term should be generally construed to include any type of spiral.

Referring to FIG. 4A, a first arrangement of the first and second set of holes 34 and 38 on the gas dispensing surface 32 of the shower head 14 is shown. In this particular embodiment, the first set of holes 34 define a first inner spiral and the second set of holes define a second spiral at the outer region of the gas dispensing surface 32 of the shower head 14. The two spirals defined by the two sets of holes 34 and 38 in this embodiment are the same.

Referring to FIG. 4B a second arrangement of the first and second set of holes 34 and 38 on the gas dispensing surface 32 is shown. In this particular embodiment, the first set of holes 34 defines a first spiral in an inner region and the second set of holes 36 defines a second spiral provided on an outer region of the gas dispensing surface 32. Unlike the previous embodiment however, a ring-shaped space 70 of no holes is provided between the two sets 34 and 38. The ring-shaped space 70 provides spacing between the first plenum 36 and the second plenum 40 within the body of the shower head 14. By providing this spacing, the two plenums 36 and 40 are physically separated from one another, making it easier to fabricate the shower head 14. In this embodiment, the spirals defined by the two sets of holes 34 and 38 in the same direction.

Referring to FIG. 4C, a third arrangement of the first and the second holes 34 and 38 on the gas dispensing surface 32 is shown. In this embodiment, the first set of holes 34 defines a first spiral that occupies the inner region, while the second set of holes 38 defines a second spiral that occupies the outer region. A ring-shaped space 70 is provided between the two sets of holes 34, 38. This embodiment differs from the previous embodiment in that the inner first spiral runs counter-clockwise, while the second outer spiral region runs clockwise.

Referring to FIG. 4D, a fourth arrangement of the first and second holes 34 and 38 on the gas dispensing surface 32 is shown. In this embodiment, the first set of holes 34 defines a first spiral that occupies the inner region, the second set of holes 38 defines a second spiral that occupies the outer region 38. A ring-shaped space 70 is provided between the two sets of holes. The scale of the two sets of holes of each spiral however is different. With the first spiral, the first set of holes 34 are more widely spaced and less dense relative to the second set of holes 38 defining the second spiral, by adjusting the scale parameter c.

Referring to FIG. 4E, a fifth embodiment is shown. In this embodiment, the second set of holes 38 is defines a spiral in the outer region of the gas dispensing surface 32. The inner region, however, is occupied by a non-spiral, symmetrical pattern. 72. With this arrangement, the first plenum is in fluid communication with the holes of the symmetrical pattern, while the second set of holes are in fluid communication with the second plenum 40 as previously described.

Referring to FIG. 4F, a sixth embodiment is shown. Three sets of holes 34, 38 and 76 are provided, defining an inner, outer and intermediate spirals respectively. With this embodiment, any two of the sets of holes 34, 38 and 76 may share a single plenum. For instance, hole sets 34 and 76 may share the first plenum 36. Alternatively, the hole sets 38 and 76 may share the second plenum 40. Alternatively, the three hole sets 34, 38, and 76 may be connected to three separate plenums.

Referring to FIG. 4G, a seventh embodiment is shown. In this embodiment, two sets of holes 34A and 34B are arranged in a non-concentric layout. A ring-shaped space 70 is also provided between the sets of holes 34A and 34B in the inner portion of the shower head and a third set of holes 38 arranged around the periphery. In alternative variations of this embodiment, the sets of holes 32A, 32B and 38 can be supplied by any number of one, two or three plenums. In cases where the holes 32A and 32B are supplied by different plenums, differences can be intentionally introduced between the left and right plenums for the purpose of fine tuning azimuthal uniformity of deposition on the wafer.

Referring to FIG. 4H, an eighth embodiment is shown. In this embodiment, the first and second sets of holes 34 (solid holes), 38 (open holes) define a pair of interleaved spirals. With interleaved spirals, each adjacent pair of holes is in fluid communication with the first plenum 36 and the second plenum 40 respectively. If each plenum is used to supply a different gas, then the mixing of the gases is thorough with the adjacent holes provided the different gases right next to one another. With a more complete mixing of the gases, more uniform thin film deposits on substrates 18 can be achieved.

Referring to FIG. 4I, a ninth embodiment is shown. In this embodiment, an inner hole pattern 34 and an outer hole pattern 38 are provided. The inner hole pattern 34 was generated using d=½, and the outer hole pattern 38 uses a different value of d that introduces a radial hole density gradient. As a result, the holes are uniformly dense inside the transition diameter and become increasingly dense radially outside of the transition diameter. Also with this embodiment, only a single plenum (40) is provided to supply gas to both sets of holes.

It should further be understood that implementations of the various embodiments described herein do not require holes to be placed on the gas dispensing surface 32 of the shower head 14 in the exact locations defined by use of any of the equations provided herein to define a given type of spiral. On the contrary, spiral patterns may be used that are merely close approximations of actual spirals defined by using the above equations. By close approximations, it is intended to mean that holes 34 and/or 38 may be offset from their equation defined counter-part points by varying degrees, such as (a) 1/1000th of an inch or less, (b) 1/100 of an inch or less (c) 1/10 of an inch or less. It should be noted that the offset may be intentional, meaning the holes are purposely offset from the hole locations defined by the above-mentioned equations or the offset can be unintentional, meaning within machining tolerances when fabricating the shower head.

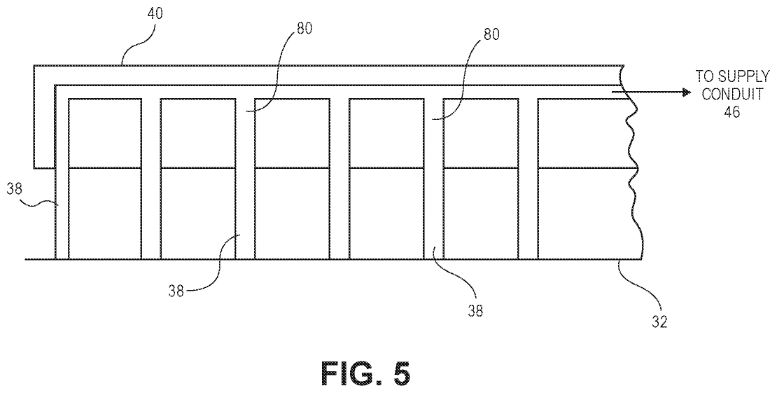

Referring to FIG. 5, a plenum in accordance with a non-exclusive embodiment of the invention is shown. In this embodiment, the plenum 40 includes a plurality of tubes 80 that are fluid communication with the holes 38 respectively. In turn, the tubes 80 are in fluid communication with the second gas conduit 46. With this arrangement, the holes 38 are individually supplied by the tubes 80. This embodiment can be similarly implemented with the first set of holes 34 and the first plenum 36.

It should be understood that the embodiments provided herein are merely exemplary and should not be construed as limiting in any regard. In general, the present application is intended to cover any a shower head having at least two set of holes defining two spiral patterns and two plenums for the two patterns respectfully.

Although only a few embodiments have been described in detail, it should be appreciated that the present application may be implemented in many other forms without departing from the spirit or scope of the disclosure provided herein. For instance, the substrate can be a semiconductor wafer, a discrete semiconductor device, a flat panel display, or any other type of work piece.

Therefore, the present embodiments should be considered illustrative and not restrictive and is not to be limited to the details given herein, but may be modified within the scope and equivalents of the appended claims.

What is claimed is:

1. A Chemical Vapor Deposition (CVD) tool, comprising
a processing chamber;
a shower head positioned within the processing chamber, the shower head having a gas dispensing surface including:
a first set of holes arranged in a first spiral pattern, the first set of holes in fluid communication with a first supply of a first gas; and
a second set of holes arranged in a second spiral pattern, the second set of holes in fluid communication with a second supply of a second gas.

2. The CVD tool of claim 1, wherein the first spiral pattern is an Archimedean spiral or an approximation of the Archimedean spiral and the first set of holes are spaced along the Archimedean spiral or the approximation of the Archimedean spiral.

3. The CVD tool of claim 2, wherein the approximation means one or more holes among the first set of holes of the first spiral pattern are offset from one or more points defined by the Archimedean spiral by 1/10 of an inch or less.

4. The CVD tool of claim 1, wherein the first set of holes arranged in the first spiral pattern are approximately provided at points along an Archimedean spiral respectively, the Archimedean spiral defined by
$$r = {c ( \frac{θ}{a} )}^{d} ,$$
where:
r is radial distance from the coordinate system origin;
θ is a polar coordinate of each point along the Archimedean spiral incremented from the θ coordinate of the previous point by a consistent value; wherein
a is a predefined constant angle; and
d changes the radial density of the Archimedean spiral.

5. The CVD tool of claim 1, wherein the second pattern of holes is arranged along a second Archimedean spiral or an approximation of the second Archimedean spiral.

6. The CVD tool of claim 1, wherein the first spiral pattern lies along a Fermat spiral.

7. The CVD tool of claim 1, wherein the first spiral pattern is a Vogel spiral pattern.

8. The CVD tool of claim 1, wherein the first set of holes arranged in the first spiral pattern define no line of symmetry.

9. The CVD tool of claim 1, wherein the first spiral pattern and the second spiral pattern are part of the same continuous pattern.

10. The CVD tool of claim 9, wherein the first spiral pattern is provided in an inner region and the second spiral pattern is provided in an outer region of the gas dispensing surface.

11. The CVD tool of claim 10, further comprising a space provided between the first spiral pattern provided in the inner region and the second spiral pattern provided in the outer region of the of the gas dispensing surface, the space providing a physical separation between:
(a) a first plenum arranged to supply the first gas to the first set of holes of the first spiral pattern; and
(b) a second plenum arranged to supply the second gas to the second set of holes of the second spiral pattern.

12. The CVD tool of claim 1, wherein the first set of holes of the first spiral pattern are arranged in clock-wise order and the second set of holes of the second spiral pattern are arranged in a counter-clockwise order on the gas dispensing surface.

13. The CVD tool of claim 1, wherein the first set of holes of the first spiral pattern have a smaller diameter and are more dense relative to the second set of holes of the second spiral pattern on the gas dispensing surface.

14. The CVD tool of claim 1, wherein the second set of holes are arranged in a non-spiral pattern on the of the gas dispensing surface.

15. The CVD tool of claim 1, further comprising a third set of holes arranged on the gas dispensing surface of the shower head, wherein any two of the first, the second and the third sets of holes are in fluid communication with a common plenum.

16. The CVD tool of claim 1, wherein the first set of holes of the first spiral pattern and the second set of holes of the second spiral pattern are interleaved on the gas dispensing surface of the shower head.

17. The CVD tool of claim 16, wherein interleaved adjacent holes of the first and second set of holes results in a mixing, external to the shower head, of first and second gasses from first and second plenums respectively.

18. The CVD tool of claim 1, wherein the first set of holes and the second set of holes are non-concentric.

19. The CVD tool of claim 18, wherein the non-concentric first and second set of holes provides for azimuthal tuning of films deposited on substrates in the processing chamber.

20. The CVD tool of claim 1, wherein the shower head further comprises:
a first plenum arranged to supply the first gas to the first set of holes arranged in the first spiral pattern; and
a second plenum arranged to supply the second gas to the second set of holes.

21. The CVD tool of claim 1, wherein the first gas and the second gas are:
(a) different gases; or
(b) a same gas.

22. The CVD tool of claim 20, wherein the first plenum is a chamber.

23. The CVD tool of claim 20, wherein the first plenum includes a set of tubes in fluid communication with the first set of holes respectively.

24. The CVD tool of claim 20, further comprising a flow rate controller arranged to control a flow rate of the first gas provided to the first plenum.

25. The CVD tool of claim 20, further comprising a first pressure controller configured to control a pressure of the first gas in the first plenum.

26. A Chemical Vapor Deposition (CVD) tool, comprising:
a processing chamber;
a shower head provided in the processing chamber, the shower head including:
a first set of holes arranged in a first Vogel spiral pattern on a gas dispensing surface of the shower head;
a first plenum arranged to supply a first gas to the first set of holes arranged in the first Vogel spiral pattern; and
a second set of holes arranged in a second Vogel spiral pattern on the gas dispensing surface of the shower head; and
a second plenum arranged to supply a second gas to the second set of holes arranged in the second Vogel spiral pattern.

27. The CVD tool of claim 26, wherein the first set of holes are provided in an inner region and the second set of holes are provided in a outer region on the gas dispensing surface of the shower head.

28. The CVD tool of claim 27, wherein the inner region and the outer region are concentric.

29. The CVD tool of claim 27, wherein the inner region and the outer region are separated by a space on the gas dispensing surface of the shower head, the space separating the first plenum and the second plenum.

30. The CVD tool of claim 27, wherein the first set of holes arranged in the first Vogel spiral pattern run in a clock-wise direction while the second set of holes arranged in the second Vogel spiral pattern run in a counter clock-wise direction.

31. The CVD tool of claim 27, wherein a first size of the first set of holes is different than a second size of the second set of holes.

32. The CVD tool of claim 27, wherein a first density of the first set of holes is different than a second density of the second set of holes.

33. The CVD tool of claim 27, wherein the shower head further comprises a third set of holes arranged in a pattern on the gas dispensing surface.

34. The CVD tool of claim 33, wherein the third set of holes shares either the first plenum with the first set of holes or the second plenum with the second set of holes.

35. The CVD tool of claim 27, wherein the first set of holes and the second set of holes are non-concentric.

36. The CVD tool of claim 27, wherein the first set of holes and the second set of holes are interleaved such that adjacent holes on the gas dispensing surface of the shower head are arranged to dispense the first gas and the second gas adjacent one another.

37. The CVD tool of claim 27, wherein the first gas and the second gas are either:
(a) the same gas; or
(d) different gases.

38. The CVD tool of claim 27, wherein the first plenum is a chamber in fluid communication with the first set of holes respectively.

39. The CVD tool of claim 27, wherein the first plenum includes a set of tubes in fluid communication with the first set of holes respectively.

40. The CVD tool of claim 27, further comprising a flow rate controller capable of individually controlling a flow rate of the first gas and the second gas into the first plenum and the second plenum respectively.

41. The CVD tool of claim 27, further comprising a pressure controller capable of individually controlling pressure of the first gas and the second gas in the first plenum and the second plenum respectively.

42. The CVD tool of claim 27, wherein the first set of holes and the second set of holes each do not define any lines of symmetry.

43. The CVD tool of claim 27, wherein the first Vogel spiral pattern approximates a Vogel spiral where one or more holes among the first set of holes are offset from points defined by the Vogel spiral by 1/10 of an inch or less.

44. A Chemical Vapor Deposition Tool (CVD), comprising:
a processing chamber; and
a shower head provided in the processing chamber, the shower head including:
a first plenum for supplying a first gas to a first set of holes arranged on a gas distributing surface of the shower head, the first set of holes arranged in a first spiral pattern; and
a second plenum for supplying a second gas to a second set of holes arranged on the gas distributing surface of the shower head.

45. The CVD tool of claim 44, wherein the second set of holes is arranged in a symmetrical pattern.

46. The CVD tool of claim 44, wherein the second set of holes is arranged in a second spiral pattern.

47. The CVD tool of claim 44, wherein the first spiral pattern is an Archimedean spiral or an approximation thereof.

48. The CVD tool of claim 44, wherein the first spiral pattern is a Vogel spiral or an approximation thereof.

49. The CVD tool of claim 44, wherein the first spiral pattern is a Fermat spiral or an approximation thereof.

50. The CVD tool of claim 46, wherein the first spiral pattern is provided in an inner region and the second spiral pattern is provided in an outer region of the gas dispensing surface of the shower head, wherein the inner region and the outer region are concentric.

51. The CVD tool of claim 50, wherein the inner region and the outer region are separated by a space on the gas dispensing surface of the shower head, the space separating the first plenum and the second plenum.

52. The CVD tool of claim 46, wherein the first set of holes arranged in the first spiral pattern run in a clock-wise direction while the second set of holes arranged in the second Vogel spiral pattern run in a counter clock-wise direction.

53. The CVD tool of claim 46, wherein a first size of the first set of holes arranged in the first spiral pattern is different than a second size of the second set of holes arranged in the second spiral pattern.

54. The CVD tool of claim 46, wherein a first density of the first set of holes arranged in the first spiral pattern is different than a second density of the second set of holes arranged in the second spiral pattern.

55. The CVD tool of claim 44, wherein the shower head further comprises a third set of holes arranged in a third pattern on the gas dispensing surface.

56. The CVD tool of claim 55, wherein the third set of holes shares either the first plenum with the first set of holes or the second plenum with the second set of holes.

57. The CVD tool of claim 1, wherein the first supply of gas and the second supply of gas is the same.

58. The CVD tool of claim 57, wherein the first set of holes and the second set of are supplied by a common plenum.

59. The CVD tool of claim 58, wherein the shower head further comprises a third set of holes, the third set of holes supplied from the common plenum.
